(19) United States
(12) Patent Application Publication
(10) Pub. No.: US 2007/0189084 A1
(43) Pub. Date: Aug. 16, 2007

(54) Reduced pin count synchronous dynamic random access memory interface

(75) Inventor: Brent D. Mulholland, Boulder, CO (US)

Correspondence Address: STERNE, KESSLER, GOLDSTEIN & FOX P.L.L.C., 1100 NEW YORK AVENUE, N.W., WASHINGTON, DC, 20005, US

(73) Assignee: Broadcom Corporation, Irvine, CA (US)

(21) Appl. No.: 11/354,028

(22) Filed: Feb. 15, 2006

(51) Int. Cl. G11C 7/00; G11C 7/10; G11C 8/00

(52) U.S. Cl. 365/189.03; 365/203; 365/230.06

(57) ABSTRACT

A method is provided for reducing the number of conductive interfaces required to interface to a SDRAM. One or more conductive interfaces can be used, during a cycle, to both transfer data and provide a command or an address to an SDRAM. More specifically, each of the conductive interfaces on a controller can be used to control one data conductive interface and one of an address, bank address, RAS, CAS, or WE conductive interface on an SDRAM. The interface for the present invention provides a lower conductive interface count ASIC with a smaller package than a conventional SDRAM interface.

### BACKGROUND OF THE INVENTION

Field of the Invention

The present invention relates generally to memory control, and more specifically, to optimizing memory access.

Related Art

A dynamic random access memory (DRAM) chip or device includes large arrays of memory cells and support logic for reading and writing data within the arrays. The arrays are arranged in rows and columns, and each memory cell within an array has a unique location or address defined by the intersection of a row and a column.

To fabricate a DRAM, a silicon substrate is etched with patterns to produce transistors, capacitors, and support circuitry. Each transistor holds a single bit. As such, if the transistor is in an open state (i.e., designated by “1”), current can flow. Otherwise, in a closed state (i.e., designated by “0”), current is blocked.

A capacitor is used to hold a charge for a memory cell. If the charge escapes, data can be lost from the memory cell. However, a DRAM is “dynamic” in the sense that support circuitry is utilized to refresh the memory to minimize data loss. This is accomplished by reading the value from a memory cell before the charge completely escapes, and writing it back. Internal counters or registers are included as part of the support circuitry to monitor or initiate the refresh cycle.

The support circuitry also includes sense amplifiers, address logic, row address select or strobe (RAS) logic, column address select or strobe (CAS) logic, read circuitry, write circuitry, and output enable logic. The sense amplifiers amplify the signal or charge detected on a memory cell. Address logic enables the selection of specific rows and columns. RAS logic and CAS logic latch and resolve row addresses and column addresses, respectively. The RAS logic and CAS logic also initiate and terminate the read and write operations. Write circuitry stores information in memory cells. Conversely, read circuitry retrieves information that is stored in the memory cells. The output enable logic prevents data from appearing at the outputs.

Since a DRAM supports “asynchronous” communications, it becomes imperative to resolve any timing conflicts among various types of signals or commands sent to the DRAM. The signals must be applied in a specific sequence with specified signal durations and delays. Typical signals include a RAS signal, CAS signal, address (ADDR) signal, write enable (WE) signal, output enable signal, and data in or out (DQ) signal.

RAS logic sends a RAS command or signal to latch a row address and initiate a memory cycle. Typically, the RAS signal is active when it is low. In other words the RAS signal is active when a higher voltage level transitions to a lower voltage level. The voltage remains low until the RAS command is no longer required.

CAS logic sends a CAS command or signal to latch the column address and initiate read or write operations. Similar to a RAS signal, the CAS signal is typically active when it is low.

Address logic sends ADDR commands or signals to select a memory location on the DRAM. The voltage level at an address at the time a RAS signal or CAS signal goes active determines the row address or column address, respectively, that is selected.

The WE signal is sent to choose a read operation or a write operation. When the WE signal has a low voltage level, a write operation is specified. A high voltage level for the WE signal indicates a read operation.

Output enable logic sends output enable commands or signals to prevent data from appearing at the output during a read operation. As such, data appears at the data outputs as it becomes available when the output enable signal is low. The output enable signal is ignored during a write operation.

The DQ signals are used for input and output. During a write operation, a voltage is applied whereby a high voltage is designated by “1” and a low voltage is designated by “0.” This voltage value is converted into an appropriate signal and stored in a specified memory cell.

Each of these signals are transmitted via a dedicated conductive interface. DRAM interface conductive interfaces occupy space and thus constrain minimum package size. Therefore, because current DRAM interfaces contain a large number of conductive interfaces, these interfaces also require a large package. Large integrated circuit packages are bulky, heavy, and make circuit board design difficult.

What is needed is a more efficient memory configuration that overcomes the above problems.

### SUMMARY OF THE INVENTION

A technique or methodology is provided to reduce the number of conductive interfaces required to interface to a memory, for example a sixteen-bit wide synchronous dynamic random access memory (SDRAM). One or more conductive interfaces are used, during a cycle, to both transfer data and provide a command or an address to an SDRAM. More specifically, each of the conductive interfaces on a controller can be used to control one data conductive interface and one of an address conductive interface, bank address conductive interface, row address select or strobe (RAS) conductive interface, column address select or strobe (CAS) conductive interface, or write enable (WE) conductive interface on an SDRAM. Therefore, the interface provides a lower conductive interface count on an application specific integrated circuit (ASIC) than that found on a typical SDRAM interface.

To enable memory access, an active command is via conductive interfaces to activate a bank and row for memory access. The active command includes a bank address and a row address. Either a Write command or a Read command is sent to initiate a write operation or read operation, respectively. The Write or Read command includes a bank address and a column address.

The data enable (DQM) signals are raised to a higher voltage to disable SDRAM data transfers over the conductive interfaces when commands or addresses are being sent. The DQM signals are dropped to a lower voltage to enable the data transfer for the read or write operations.

A chip select (CS) signal is activated to enable the conductive interface to receive a RAS signal, a CAS signal, or a WE signal. The CS signal is raised to a higher voltage level to place the signal in an inactive state, which enables the conductive interface to disregard a RAS signal, a CAS signal, or a WE signal during data transfers.

### BRIEF DESCRIPTION OF THE DRAWINGS/FIGURES

The accompanying drawings, which are incorporated herein and form part of the specification, illustrate the present invention and, together with the description, further serve to explain the principles of the invention and to enable a person skilled in the pertinent art(s) to make and use the invention. In the drawings, like reference numbers indicate identical or functionally similar elements. Additionally, the leftmost digit(s) of a reference number identifies the drawing in which the reference number first appears.

FIG. 1 illustrates an example of transferring a command/address or data during the same clock cycle on an SDRAM interface;

FIG. 2 illustrates various states of an SDRAM interface in an example of the invention;

FIGS. 3A-3B illustrate another example of accessing an SDRAM over a single conductive interface;

FIG. 4 illustrates a timing diagram for accessing an SDRAM over a single conductive interface;

FIG. 5 illustrates another timing diagram for accessing an SDRAM over a single conductive interface;

FIG. 6 illustrates another timing diagram for accessing an SDRAM over a single conductive interface;

FIG. 7 illustrates another timing diagram for accessing an SDRAM over a single conductive interface;

FIG. 8A illustrates a block diagram of an SDRAM system;

FIG. 8B illustrates a multi-banked SDRAM system; and

FIG. 9 illustrates an SDRAM.

### DETAILED DESCRIPTION OF THE INVENTION

This specification discloses one or more embodiments that incorporate features of this invention. The embodiment(s) described, and references in the specification to “one embodiment”, “an embodiment”, “an example embodiment”, etc., indicate that the embodiment(s) described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the relevant art(s) to effect such feature, structure, or characteristic in connection with other embodiments whether or not explicitly described.

Multi-banked, synchronous dynamic random access memory (SDRAM) devices allow a memory controller to achieve higher bandwidth than conventional dynamic random access memory (DRAM) devices. This is achieved by allowing Active and Precharge commands to be sent to the SDRAM from one bank while data from another bank is being transferred. The overlapping of commands with data allows data to be transferred on every clock cycle if the data transfer for each command is in the same direction as the previous command. If the data transfer for a new command is in the opposite direction from the previous command, a small number of cycles do not allow data to be transferred so the direction of the data bus can be changed without both the memory controller and the SDRAM driving the data outputs at the same time.

As used herein, a conductive interface includes a means to transfer electrical energy across a common boundary between electrical components. Examples of a conductive interface include, and are not limited to, a pin, a tab, a pad, and a lead.

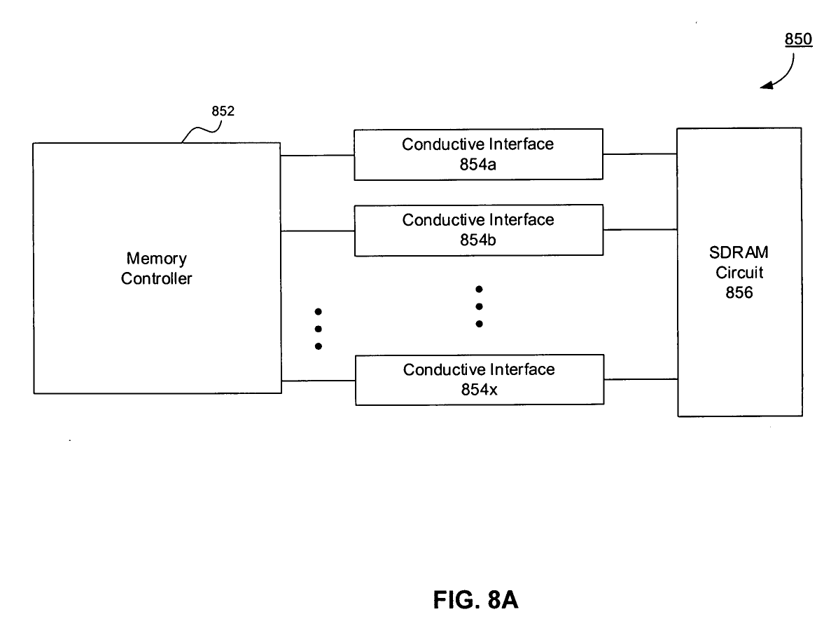

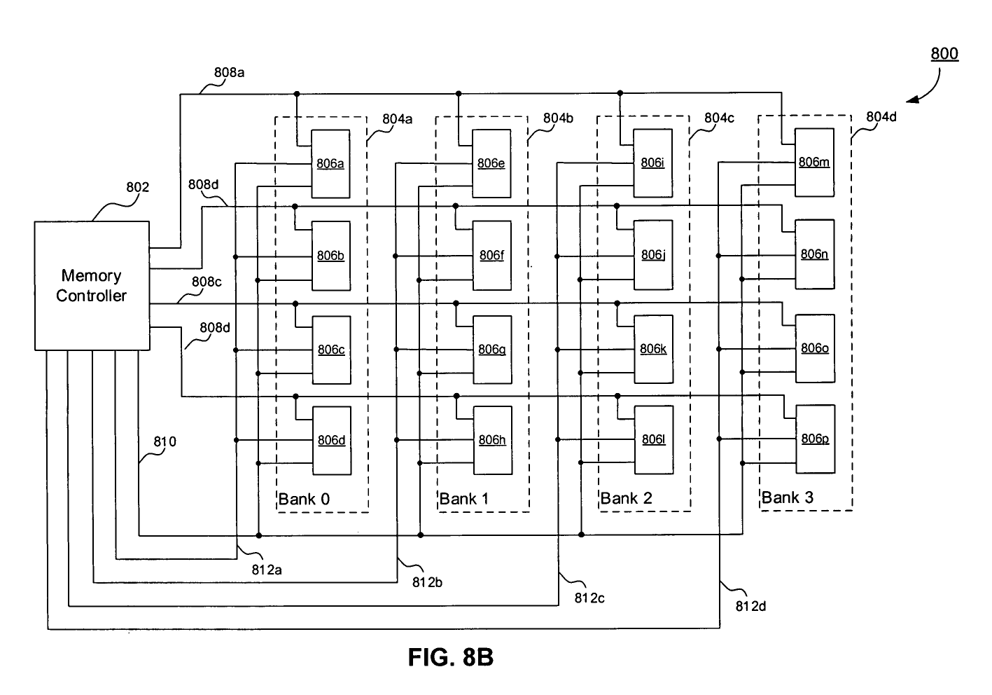

FIG. 8A illustrates an embodiment of an SDRAM system 850 that is useful for explaining various aspects of the present invention. SDRAM system 850 includes a memory controller 852 that is coupled to an SDRAM circuit 856 via at least one conductive interface 854a-854x. In one example, the SDRAM circuit 856 and the conductive interfaces 854a-854x are part of the same integrated circuit package.

FIG. 8B illustrates an embodiment of a multi-banked SDRAM system 800 that is useful for explaining various aspects of the present invention. SDRAM system 800 includes a memory controller 802 that is coupled to a plurality of SDRAM banks 804a-804d (referred to collectively herein as SDRAM bank 804). Each SDRAM bank 804 includes a plurality of SDRAM chips 806a-806p (referred to collectively herein as SDRAM 806). More specifically, SDRAM bank 804a includes SDRAM chips 806a-806d, SDRAM bank 804b includes SDRAM chips 806e-806h, SDRAM bank 804c includes SDRAM chips 806i-806l, and SDRAM bank 804d includes SDRAM chips 806m-806p. It should be understood that the quantity of SDRAM banks 804a-804d and SDRAM chips 806a-806p have been provided for illustrative purposes. These quantities can be increase or decreased as desired by the system architect.

Memory controller 802 sends or receives data, addresses, and commands to the SDRAM chips 806 over one or more conductive interfaces.

The conductive interfaces are represented by data lines 808a-808d, address line 810, and command lines 812a-812d. Memory controller 802 accesses each SDRAM chip 806 over data lines 808a-808d to send or receive data in response to read or write operations with a selected SDRAM chip 806. Address line 810 is used to send address (ADDR) signals or clock (CLK) signals to the SDRAM chips 806. Command lines 812a-812d are used to send various commands to the SDRAM chips 806. For example, a bank address (BA) command or signal is sent to select a specific SDRAM bank 804a-804n.

A chip select (CS) command or signal is sent to select a specific SDRAM chip 806a-806n.

A memory controller 802 can utilize a dedicated conductive interface for sending data over data lines 808a-808d, another dedicated conductive interface for sending addresses over address line 810, and another dedicated conductive interface for sending commands over command lines 812a-812d. However as described in greater details below, the quantity of conductive interfaces that are required to interface to a selected SDRAM 806 can be reduced by utilizing a single conductive interface to provide data and either a command or an address to the SDRAM 806.

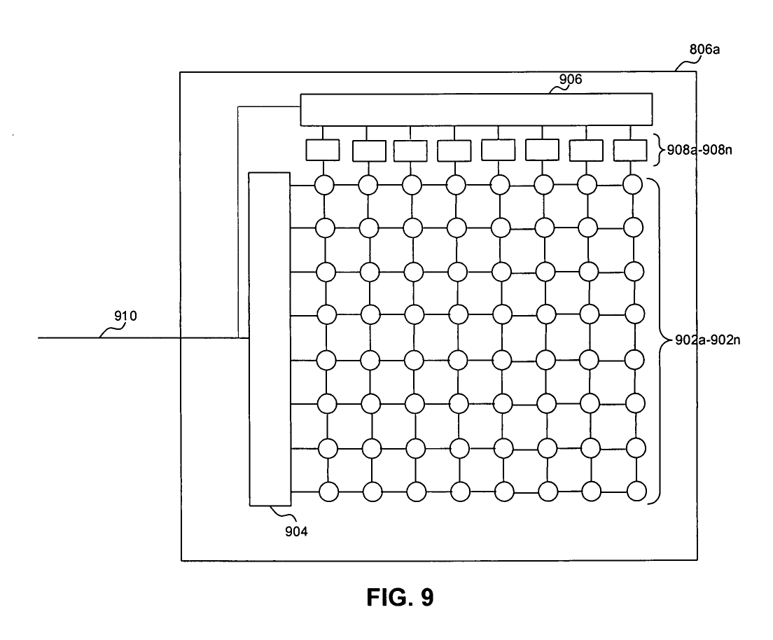

FIG. 9 illustrates various components of SDRAM chip 806a (from FIG. 8B). The components include an array of memory cells 902a-902n, row address select or strobe (RAS) logic 904, column address select or strobe (CAS) logic 906, and a plurality of sense amplifiers 908a-908n. Data, address, and command signals are received over SDRAM interface 910.

Each memory cell 902a-902n represents a single bit of data, and is created by pairing a transistor and capacitor. The capacitor holds the data bit (i.e., “0” or “1”). For example, the capacitor is read as holding a “1” if the level of charge in the capacitor exceeds fifty percent. The capacitor is read as holding a “0” if the level of charge is fifty percent or less. The transistor serves as a switch that allows the control circuitry on SDRAM chip 806a to read the capacitor or change its state.

The array of memory cells 902a-902n is addressed by rows and columns. RAS logic 904 and CAS logic 906 receive RAS signals and CAS signals, respectively, to latch a row address and column address, respectively. The sense amplifiers 908a-908n are access transistors, and are connected to a respective column within the array of memory cells 902a-902n.

To read a location or address in the array of memory cells 902a-902n, memory controller 802 sends a row address (i.e., RAS signal) that is received by RAS logic 904. RAS logic 904 causes the specified row to be read and connected to the bank of sense amplifiers 908a-908n. Sense amplifiers 908a-908n read the contents of all the memory cells 902a-902n in the specified row.

After memory controller 802 sends a column address (i.e., CAS signal) to CAS logic 906, the specified column is read by CAS logic 906. The output is selected from the sense amplifier 908a-908n corresponding to the specified column. The output value is then sent to the data input/output conductive interface for the SDRAM chip 806a. Afterwards, the entire row on the sense amplifiers 908a-908n is written back (i.e., refreshed).

To write data to the SDRAM chip 806a, a row address and column address is sent to RAS logic 904 and CAS logic 906, as described above. However instead of sending to memory controller 802 an output value that is selected from the sense amplifiers 908a-908n, data is transferred to the SDRAM 806a to change the output value. Afterwards, the entire row on the sense amplifiers 908a-908n (along with the changed value) is written back into the memory cells 902a-902n.

As discussed, a technique or methodology is provided herein to reduce the number of conductive interfaces that are required to interface to a SDRAM (such as SDRAM 806). In one example, the SDRAM is sixteen-bits wide. If one stipulates that a command to the SDRAM is not allowed during a cycle in which data is transferred, one could use the same conductive interfaces to provide a data and either a command or an address to the SDRAM. More specifically, in one example, each of up to sixteen conductive interfaces on a controller (such as memory controller 802) can be used to control one data conductive interface and one conductive interface for an address command, BA command, RAS command, CAS command, or write enable (WE) command on an SDRAM. Therefore, the interface would allow a reduction in the number of conductive interfaces on an application specific integrated circuit (ASIC) than a typical SDRAM interface.

In an embodiment, the following conductive interfaces are controlled individually: clock (CLK), clock enable (CKE), CS, and data enable (DQM[1:0]). The following conductive interfaces are combined with the data bus: data (DQ[15:0]), RAS, CAS, WE, BA[1:0], and address (ADDR[10:0]).

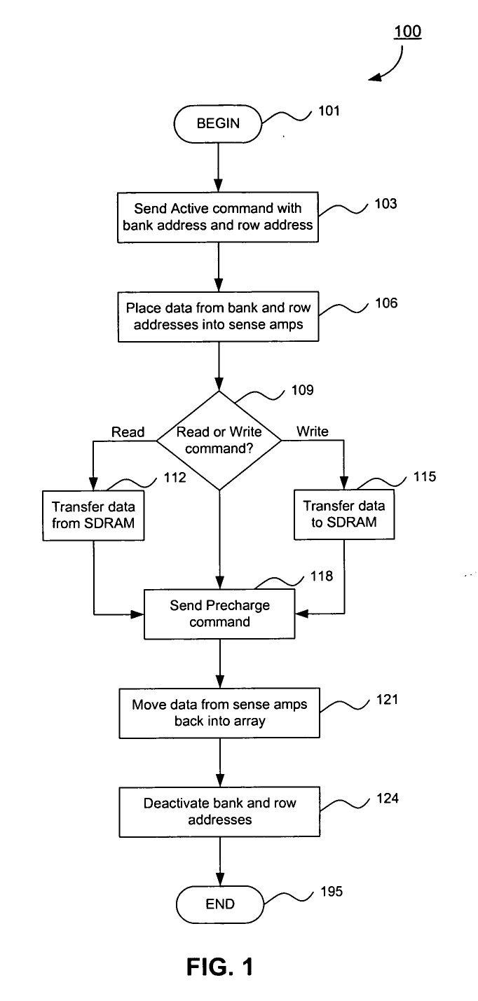

Referring to FIG. 1, flowchart 100 shows an example of a control flow for accessing an SDRAM (such as SDRAM 806) over a single conductive interface, thereby reducing the conductive interface count. The control flow begins at step 101 and passes immediately to step 103. At step 103, an Active command with a bank address and a row address is sent to the SDRAM. The Active command charges and activates the bank at the specified bank address and row address.

At step 106, the SDRAM places a page of data that is associated with the bank address and the row address into sense amplifiers. At step 109, either a Read command or a Write command is sent to the SDRAM.

If a Read command is sent, data is transferred from the SDRAM at step 112. If a Write command is sent, data is transferred to the SDRAM at step 115.

When the data transfer (at step 112 or step 115) is complete, a Precharge command is sent to the SDRAM at step 118. The Precharge command turns-off the bank array for the previous access. The Precharge command closes the page for the current access, so that the next access command can be applied to another memory page. Alternatively, a transfer could be halted by a “burst stop” command instead of a Precharge command.

At step 121, data is moved from the sense amplifiers (such as sense amplifiers 908a-908n) back into the SDRAM array (such as, memory cells 902a-902n). At step 124, the bank address and row address (from step 103) is deactivated. After the deactivation, the control flow ends as indicated at step 195.

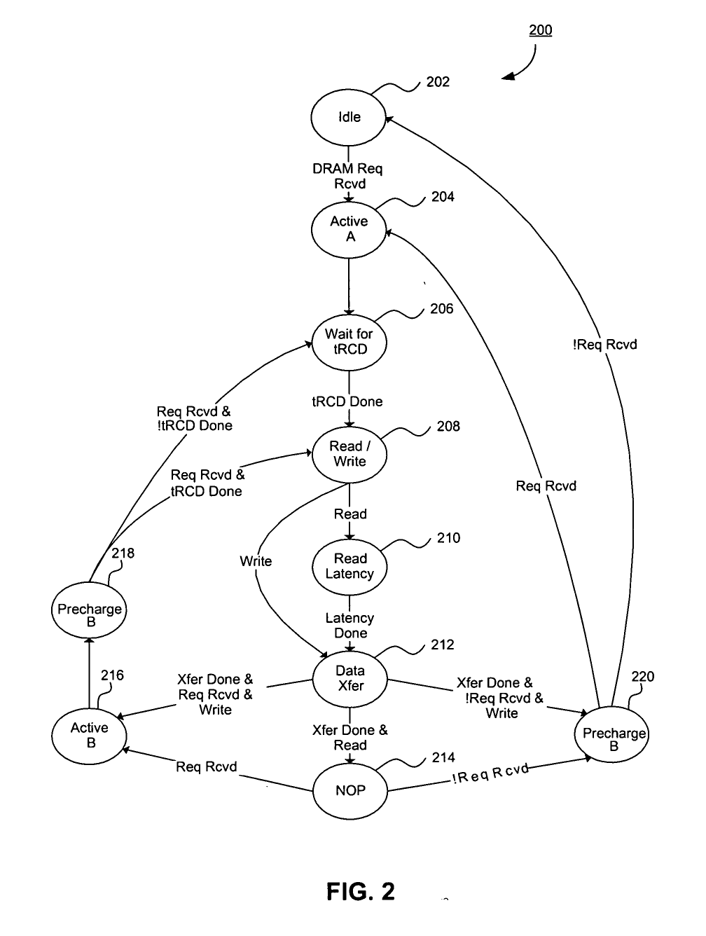

FIG. 2 illustrates an operational flow 200 of an example of the invention for various states of an SDRAM interface (such as SDRAM interface 910). Operational flow 200 is useful for implementing aspects of, for example, method 100. Idle state 202 indicates that the SDRAM interface has been idled. Following the idle state 202, the SDRAM interface enters an Active A state 204, which indicates that an Active command has been issued with a bank address and row address.

A Waiting state 206 follows the Active A state 204. Upon termination of the specified waiting period, the SDRAM interface enters a Read/Write state 208, depending on whether a Read command or a Write command has been issued.

If a Read Command has been sent, the SDRAM interface enters a Read Latency state 210, which lasts a predetermined quantity of cycles. In the Read Latency state 210, the ASIC changes the direction of data flow on the SDRAM interface from output to input to receive the Read data. Afterwards, data is transferred from the SDRAM during a Data Transfer state 212. The SDRAM interface thereafter enters a no operation (NOP) state 214 to mark completion of the data transfer. The NOP state 214 is also used to change the direction of data flow on the SDRAM interface from input to output so the ASIC can transfer a new command.

If the next Active command (Read or Write) is ready, the Active command is sent with a bank address and row address, and places the SDRAM interface into an Active B state 216. A Precharge command is sent to place the SDRAM interface into a Precharge B state 218, and the process repeats itself with the Waiting state 206 or the Read/Write state 208.

If, on the other hand, the next Active command (Read or Write) is not ready (following the NOP state 214), a Precharge command is sent to place the SDRAM interface into a Precharge B state 220. The SDRAM interface thereafter enters either into the Active A state 204 or an Idle state 202 where it awaits receipt of another Active command.

Referring back to Read/Write state 208, if a Write command has been sent, the SDRAM interface goes directly to the Data Transfer state 212, whereupon data is transferred to the SDRAM. Upon completion of the data transfer, the SDRAM interface enters the Active B state 216 if the next Active command (Read or Write) is ready, or the Precharge B state 220 if the next Active command (Read or Write) is not ready.

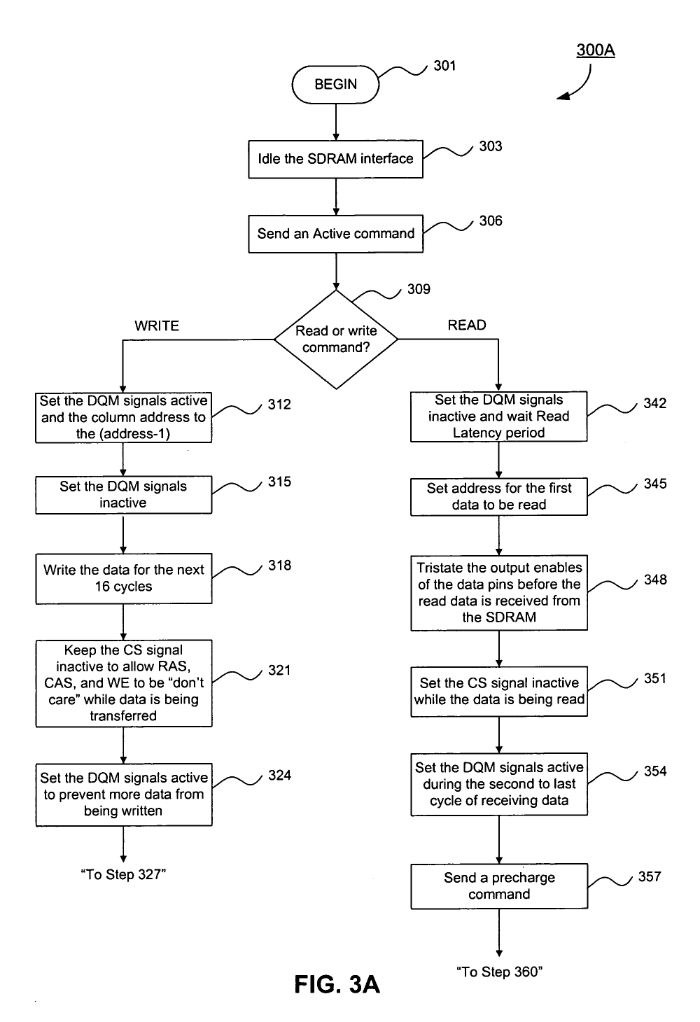

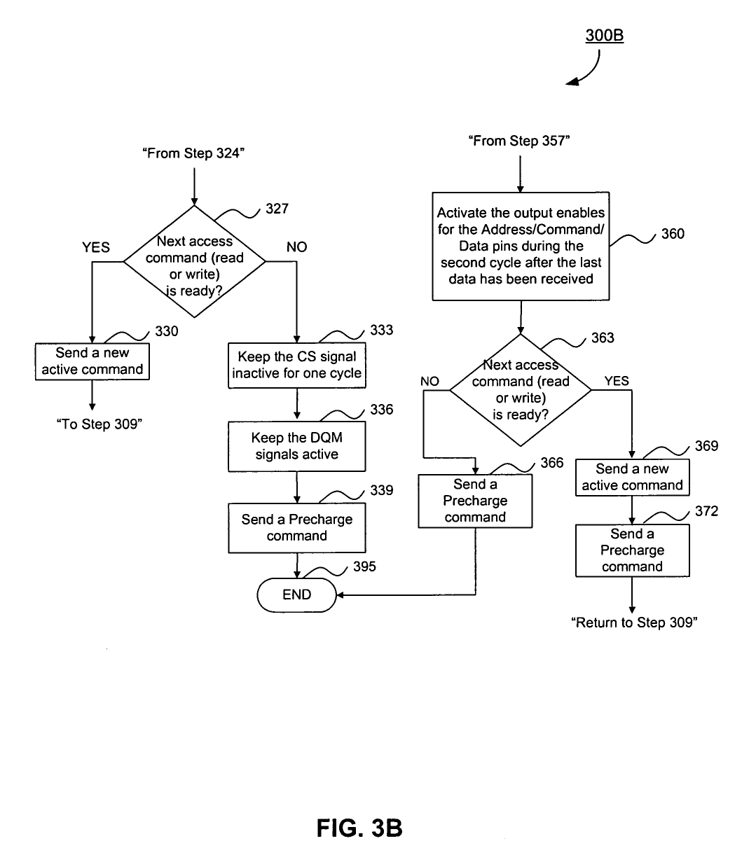

Referring to FIGS. 3A and 3B, flowcharts 300A-300B show another example of a control flow for accessing an SDRAM (such as SDRAM 806) over a single conductive interface, thereby reducing the conductive interface count. The control flow begins at step 301 and passes immediately to step 303. At step 303, the SDRAM interface (such as SDRAM interface 910) is idled. At step 306, an Active command is sent to the SDRAM. At step 309, it is determined whether the access is a Write or Read command.

If the access is a write, then at step 312, the memory controller sets the DQM bits to active and the column address to the specified address in the Write command minus one (i.e., “address −1”). This is because, for an SDRAM, data must be written during a Write command. This sequence masks the first write and data will then be written to the correct locations. If the starting location is at the beginning of a page (i.e., column address 0x00), the address during the Write command must be 0xFF. The SDRAM would correctly wrap the next address to 0x00.

At step 315, set the DQM signals inactive. At step 318, the data is written for the next sixteen cycles with the DQM signals being inactive. At step 321, a CS signal is kept inactive to allow an RAS signal, a CAS signal, and a WE signal to be in a “don't care” state while data is being transferred. At step 324, the DQM signals are set active to prevent more data from being written.

At step 327, it is determined whether the next access (Read or Write) to the SDRAM is ready. If the next access is ready, a new Active command is sent to the SDRAM at step 330. Thereafter, the control flow returns to step 309 and the process is repeated.

If the next access is not ready, the SDRAM continues to keep the CS signal inactive for one cycle at step 333. At step 336, the DQM signals remains active, and at step 339, a Precharge command is sent. Thereafter, the control flow ends at step 395.

Referring back to step 309, if a Read command is detected, control passes to step 342. At step 342, the DQM signals are set inactive to remove the tristate from the SDRAM outputs, allowing data to be read and starting a Read Latency period. The DQM signals do not need to be set because data is not read until the SDRAM Read Latency has occurred.

At step 345, the starting address for the first data to be read is sent during the Read command. At step 348, the memory controller tri-states the output enables of the data conductive interfaces before the read data is received from the SDRAM. At step 351, the CS signal is kept inactive while data is being read. At step 354, the DQM signals are set active during the second to the last cycle of receiving data, and kept active until a Precharge command is sent at step 357. At step 360, during the second cycle after the last data has been received, the output enables for the Address/Command/Data conductive interfaces are activated.

At step 363, it is determined whether the next access (Read or Write) command is ready. If the next command is not ready, a Precharge command is sent at step 366, and the control flow ends at step 395.

Otherwise, an Active command is sent at step 369, followed by a Precharge command at 372. Thereafter, the control flow returns to step 309 and the process is repeated.

As described above, an Active command for a subsequent command is sent after a data transfer has been completed for an earlier command. Alternatively, the Active command for the next command could be sent to the SDRAM before the data for the current command has been sent. This increases bus efficiency.

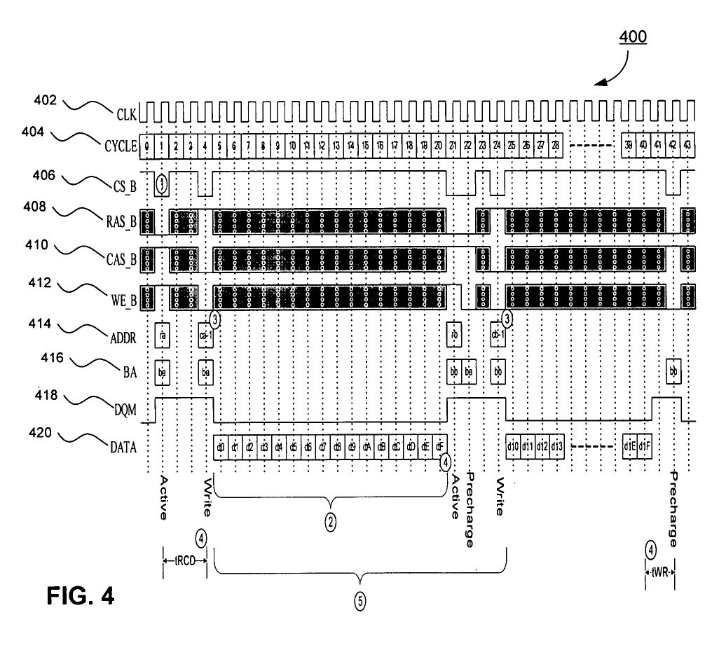

FIG. 4 illustrates a timing diagram 400 for an example of accessing an SDRAM (such as SDRAM 806) over a single conductive interface, thereby reducing the conductive interface count. Timing diagram 400 shows an example for executing two consecutive Write access commands on an SDRAM. Timing diagram 400 includes CLK signals 402, timing cycles 404, CS for memory array B (CS_B) signals 406, RAS for memory array B (RAS_B) signals 408, CAS for memory array B (CAS_B) signals 410, WE for memory array B (WE_B) signals 412, ADDR 414 signals, BA signals 416, DQM signals 418, and DATA signals 420.

Referring to timing cycles 404, an active command is sent when the timing cycles 404 are “1”. As can be seen, CS_B signals 406 are low when active and high when inactive. The active command includes a bank address shown by BA signals 416 and row address shown by ADDR signals 414.

RAS_B signals 408, CAS_B signals 410, and WE_B signals 412 are only valid when CS_B signals 406 are active or low.

The DQM signals 418 are high when active and low when inactive.

Therefore, when the DQM signals 418 are low or inactive, data can be written as shown by DATA signals 420. The muxed pads can output data during this time.

The DQM signals 418 are high or active when it is necessary to prevent data from being written. The RAS_B signals 408, CAS_B signals 410, WE_B signals 412, ADDR signals 414, and BA signals 416 can be output during this time.

A Write command is sent when the timing cycles 404 are “4.” The Write command includes a bank address shown by BA signals 416 and column address shown by ADDR signals 414. The column address for a Write command must be one less than the starting address (or 0xFF if the starting address is “0”) because the data write is masked during the Write command by the DQM signals 418 being high.

The CAS_B signal 410 is low and the RAS_B signal 408 is high when a column address is being sent. Conversely, the RAS_B signal 408 is low and the CAS_B signal 410 is high when a row address is being sent.

BA signals 416 show that the bank access for the first Write command occurs when the timing cycles 404 are “1,” “4,” and “22.” Bank access for the second Write command occurs when the timing cycles 404 are “21,” “24,” and “42.”

In FIG. 4, the page burst includes a sixteen-word transfer as shown by “d0 . . . dF” and “d10 . . . d1F” in DATA signals 420. Although a sixteen-word transfer is described, any length of transfer (up to a full page) can occur per access.

The latency between receiving an Active command and Write command (shown by “tRCD”) is three clock cycles, and the latency between the final word in the data write and a Precharge command (shown by “tWR”) is two clock cycles.

The data efficiency for the write-to-write access depicted in FIG. 4 can be measured by dividing the cycles of data being transferred by the total cycles per command. The data is transferred in sixteen cycles. The total cycles per command (i.e., measured from one Write command to the next Write command) is twenty cycles. Hence, in one example, the data efficiency is eighty percent.

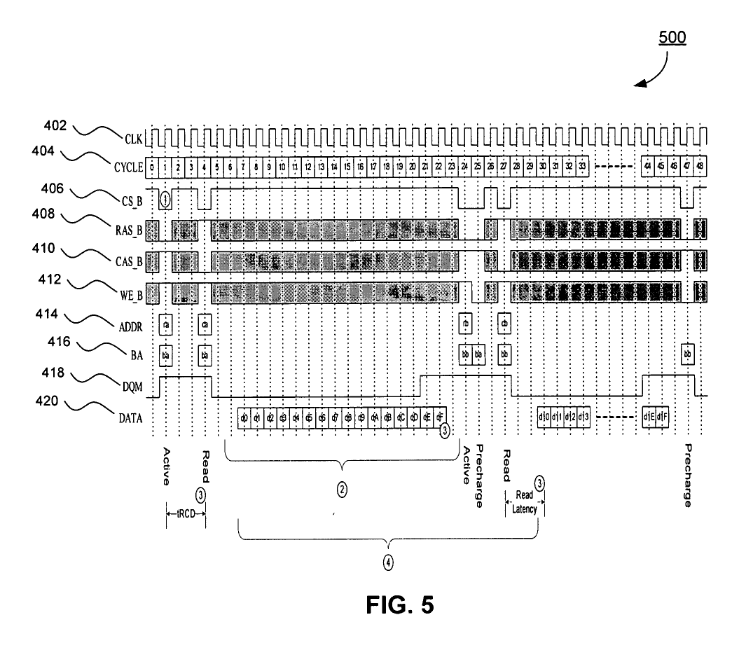

FIG. 5 illustrates another example. FIG. 5 contains timing diagram 500, which shows the execution of two consecutive read access commands on an SDRAM (such as SDRAM 806) over a single conductive interface. As described above, CS_B signals 406 are active when they are low. RAS_B signals 408, CAS_B signals 410, and WE_B signals 412 are only valid when CS_B signals 406 are active.

The latency between receiving an Active command and a Read command (shown by “tRCD”) is three clock cycles. The Read command is sent when the timing cycles 404 are “4,” and includes a bank address shown by BA signals 416 and a column address shown by ADDR signals 414. Following the Read command, the DQM signal 418 goes inactive or low, and a three clock Read Latency precedes the sixteen word data transfer shown by “d0 . . . dF.”

It should be noted that the CS_B signals are inactive when data is being read. During this period, the muxed pads are configured as inputs. Otherwise when data is not being read and the CS_B signals are active, the muxed pads are configured as outputs with the RAS_B signals 408, CAS_B signals 410, WE_B signals 412, ADDR signals 414, and BA signals 416 on the outputs.

BA signals 416 show that the bank access for the first Read command occurs when the timing cycles 404 are “1,” “4,” and “25.” The bank access for the second Read command occurs when the timing cycles 404 are “24,” “27, ” and “47.”

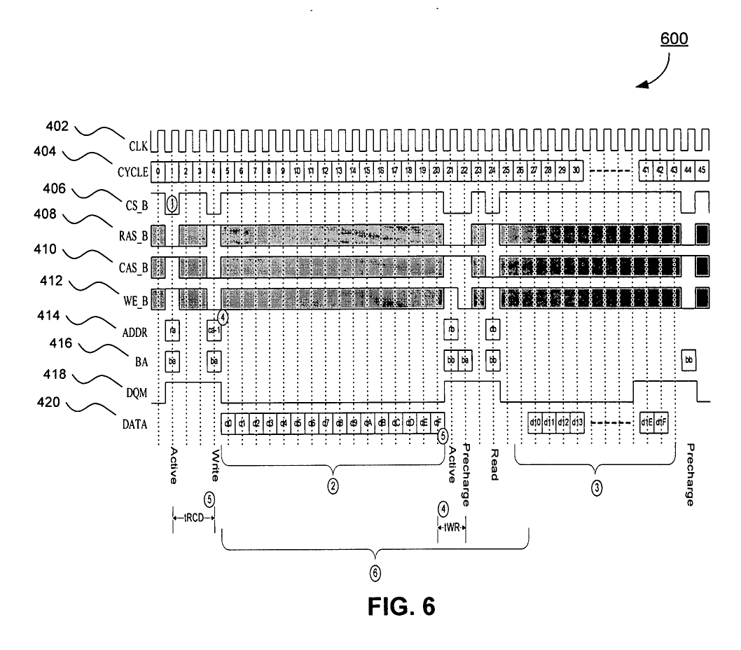

FIG. 6 illustrates an example. FIG. 6 contains timing diagram 600, which shows the execution of Write-to-Read access commands over a single conductive interface on an SDRAM (such as SDRAM 806). An Active command and Write command are sent when the timing cycles 404 are “1” and “4,” respectively. As discussed above with respect to FIG. 4, the Active and Write commands are sent when the CS_B signals 406 are low or active. The Active commands include a bank address shown by BA signals 416 and row address shown by ADDR signals 414. The Write commands include a bank address shown by BA signals 416 and column address shown by ADDR signals 414. The latency between receiving the Active command and Write command (shown by “tRCD”) is three clock cycles.

Following the data write (shown by “d0 . . . dF”), an Active command and Read command are sent when the timing cycles 404 are “21” and “24” respectively. A Precharge command follows the second Active command when the timing cycles 404 are “22.” The latency between the final word in the data write and the Precharge command (shown by “tWR”) is two clock cycles.

As discussed above with respect to FIG. 5, the Active and Read commands are sent when the CS_B signals 406 are low or active. A three clock cycle Read Latency precedes the sixteen word data transfer shown by “d10 . . . d1F.”

BA signals 416 shows that the bank access for the Write command occurs when the timing cycles 404 are “1,” “4,” and “22.” The bank access for the Read command occurs when the timing cycles 404 are “21,” “24,” and

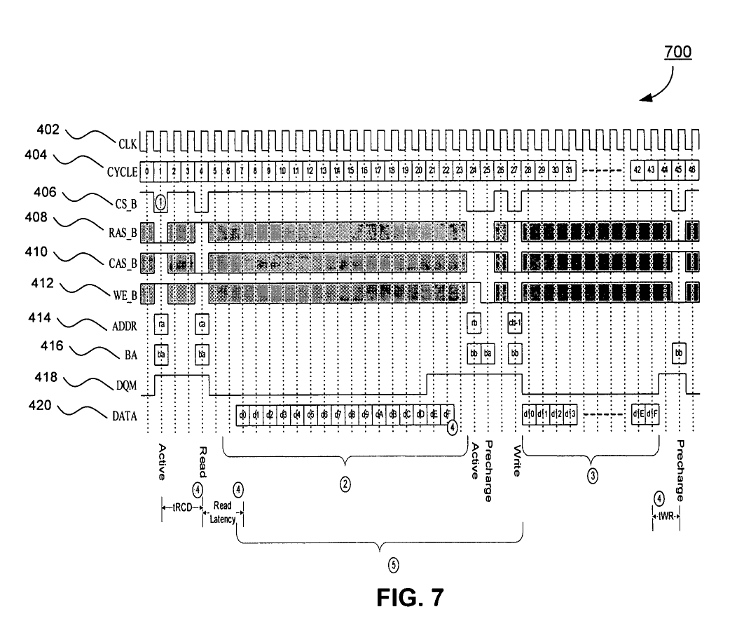

FIG. 7 illustrates an example. FIG. 7 contains timing diagram 700, which shows the execution of Read-to-Write access commands over a single conductive interface on an SDRAM (such as SDRAM 806). An Active command and Read command are sent when the timing cycles 404 are “1” and “4,” respectively. As discussed above with respect to FIG. 5, the Active and Read commands are sent when the CS_B signals 406 are low or active. The Active commands include a bank address shown by BA signals 416 and row address shown by ADDR signals 414. The Read commands include a bank address shown by BA signals 416 and column address shown by ADDR signals 414. The latency between receiving the Active command and Read command (shown by “tRCD”) is three clock cycles. A three clock cycle Read Latency precedes the sixteen word data transfer shown by “d10 . . . d1F.”

An Active command and a Write command are sent after the data transfer when the timing cycles 404 are “24” and “27,” respectively. A Precharge command follows the second Active command when the timing cycles 404 are “25.” The latency between the final word in the data write and the Precharge command (shown by “tWR”) is two clock cycles.

BA signals 416 shows that the bank access for the Read command occurs when the timing cycles 404 are “1,” “4,” and “25.” The bank access for the Write command occurs when the timing cycles 404 are “24,” “27,” and “45.”

Although a sixteen-bit wide SDRAM has been described in examples above, in other examples, the techniques for reducing conductive interface count is implemented with different data width SDRAMs. In other examples, the conductive interface reduction techniques described herein are implemented with SDRAMs having a width other than sixteen bits.

In another example of the invention, the conductive interface reduction techniques are used on a double data rate (DDR) SDRAM.

FIGS. 1-9 are useful for explaining aspects of the present invention. It should be understood that embodiments of the present invention could be implemented in hardware, firmware, software, or a combination thereof. In such an embodiment, the various components and steps would be implemented in hardware, firmware, and/or software to perform the functions of the present invention. That is, the same piece of hardware, firmware, or module of software could perform one or more of the illustrated blocks (i.e., components or steps).

In this document, the terms “computer program medium” and “computer usable medium” are used to generally refer to media such as a removable storage unit, a hard disk installed in hard disk drive, and signals (i.e., electronic, electromagnetic, optical, or other types of signals capable of being received by a communications interface). These computer program products are means for providing software to a computer system. The invention, in an embodiment, is directed to such computer program products.

In an embodiment where aspects of the present invention is implemented using software, the software can be stored in a computer program product and loaded into computer system using a removable storage drive, hard drive, or communications interface. The control logic (software), when executed by a processor, causes the processor to perform the functions of the invention as described herein.

In another embodiment, aspects of the present invention are implemented primarily in hardware using, for example, hardware components such as application specific integrated circuits (ASICs). Implementation of the hardware state machine so as to perform the functions described herein will be apparent to one skilled in the relevant art(s).

In yet another embodiment, the invention is implemented using a combination of both hardware and software.

While various embodiments of the present invention have been described above, it should be understood that they have been presented by way of example, and not limitation. It will be apparent to one skilled in the relevant art(s) that various changes in form and detail can be made therein without departing from the spirit and scope of the invention. Thus, the present invention should not be limited by any of the above-described exemplary embodiments, but should be defined only in accordance with the claims and their equivalents.

It is to be appreciated that the Detailed Description section, and not the Title, Summary, and Abstract sections, is intended to be used to interpret the claims. The Title, Summary, and Abstract sections may set forth one or more but not all exemplary embodiments of the present invention as contemplated by the inventor(s), and thus, are not intended to limit the present invention and the appended claims in any way.

What is claimed is:

1. A method of accessing a memory via a conductive interface, comprising the steps of:
sending a command via the conductive interface to enable memory access;
transferring a first data from the memory via the conductive interface upon receipt of a read command; and
transferring a second data to the memory via the conductive interface upon receipt of a write command.

2. The method according to claim 1, wherein the sending further comprises sending an active command over the conductive interface to activate a bank for memory access.

3. The method according to claim 2, wherein the sending further comprises sending a bank address.

4. The method according to claim 2, wherein the sending further comprises sending a row address.

5. The method according to claim 1, wherein the sending further comprises sending a chip select signal to enable the conductive interface to receive at least one of a row address strobe signal, a column address strobe signal, and a write enable signal.

6. The method according to claim 1, wherein the sending further comprises ending a data enable signal to disable the data transfer via the conductive interface.

7. The method according to claim 1, wherein the transferring a first data from the memory further comprises sending a read command over the conductive interface to enable the data transfer from the memory.

8. The method according to claim 7, wherein the transferring a first data from the memory further comprises sending a data enable signal to enable the transferring data from the memory.

9. The method according to claim 8, wherein the transferring a first data from the memory further comprises waiting a latency period upon receipt of the data enable signal prior to the transferring data from the memory.

10. The method according to claim 8, wherein the transferring a first data from the memory further comprises altering a state of the data enable signal during a second to a last cycle of the transferring a first data from the memory.

11. The method according to claim 7, wherein the transferring a first data from the memory further comprises sending a chip select signal to enable the conductive interface to disregard at least one of a row address strobe signal, a column address strobe signal, or a write enable signal.

12. The method according to claim 1, wherein the transferring a second data to the memory further comprises sending a write command over the conductive interface to enable the data transfer to the memory.

13. The method according to claim 12, wherein the transferring a second data to the memory further comprises sending a data enable signal to enable the transferring data to the memory.

14. The method according to claim 12, wherein the transferring a second data to the memory further comprises sending a chip select signal to enable the conductive interface to disregard at least one of a row address strobe signal, a column address strobe signal, or a write enable signal.

15. The method according to claim 1, further comprising the step of:
sending a precharge command to turn-off a previous memory access.

16. The method according to claim 15, further comprising the step of:
sending an active command over the conductive interface to activate a bank for a subsequent memory access prior to sending the precharge command, wherein the active command is sent upon completion of at least one of transferring a first data from the memory and transferring a second data to the memory.

17. The method according to claim 1, wherein the conductive interface is a pin.

18. A method of accessing a memory via a single conductive interface, comprising the steps of:
sending via the conductive interface at least one of a command or an address to enable memory access; and
transferring data via the conductive interface upon receipt of a read command or a write command.

19. The method according to claim 18, wherein the sending step further comprises sending at least one of a bank address, a row address, and a column address via the conductive interface.

20. The method according to claim 18, wherein the sending step further comprises sending at least one of a row address strobe command, a column address strobe command, and a write enable command via the conductive interface.

21. The method according to claim 18, wherein the conductive interface is a pin.
